(19) United States
(12) Patent Application Publication
(10) Pub. No.: US 2013/0285247 A1
(43) Pub. Date: Oct. 31, 2013

(54) SEMICONDUCTOR DEVICE AND PRODUCTION METHOD OF THE SAME

(71) Applicant: Renesas Electronics Corporation, Kasasaki-shi (JP)

(72) Inventors: Hiroyasu Minda, Kanagawa (JP); Hiroshi Yamamoto, Kanagawa (JP)

(21) Appl. No.: 13/859,190

(22) Filed: Apr. 9, 2013

(30) Foreign Application Priority Data
Apr. 26, 2012 (JP) 2012-100601

(51) Int. Cl. H01L 21/48; H01L 23/538

(52) U.S. Cl. CPC H01L 21/4857; H01L 23/5384
USPC 257/758; 438/612

(57) ABSTRACT

A semiconductor device capable of performing sufficient power supply while suppressing an increase in a manufacturing cost. The semiconductor device has a semiconductor substrate, a multilayer interconnection layer provided over the semiconductor substrate, an Al wiring layer that is provided over the multilayer interconnection layer and has pad parts, and a redistribution layer that is provided over the Al wiring layer and is coupled with the Al wiring layer, in which the redistribution layer is comprised of a metal material whose electric resistivity is lower than that of Al and is not formed over the pad parts.

### CROSS-REFERENCE TO RELATED APPLICATIONS

The disclosure of Japanese Patent Application No. 2012-100601 filed on Apr. 26, 2012 including the specification, drawings and abstract is incorporated herein by reference in its entirety.

### BACKGROUND

The present invention relates to a semiconductor device and a production method of the semiconductor device, and more specifically to a semiconductor device that has a redistribution structure and a production method of the semiconductor device.

In a semiconductor package, from a viewpoint of aiming at improvement in working speed, etc., performing sufficient power supply to a semiconductor chip is required. For example, a technology disclosed by Japanese Unexamined Patent Application Publication No. 2009-4721 forms redistribution that links a bonding pad and an internal wiring portion.

### SUMMARY

In Japanese Unexamined Patent Application Publication No. 2009-4721, redistribution is formed so as to cover a bonding pad. In this case, in consideration of its connectivity with a bonding wire, an uppermost layer of the redistribution needs to be comprised of Au. However, in the case where Au is used as a material that forms the redistribution, a manufacturing cost of a semiconductor device will increase. Other problems and new features will become clear from a specification and accompanying drawings of the present invention.

According to one aspect of this invention, in a semiconductor device that has a redistribution layer comprised of a metal material whose electric resistivity is lower than that of Al over an Al wiring layer having a pad part, the above-mentioned redistribution layer is not provided over the above-mentioned pad part.

According to the one aspect of this invention, a semiconductor device capable of performing sufficient power supply while suppressing an increase in the manufacturing cost is provided.

### BRIEF DESCRIPTION OF THE DRAWINGS

FIG. 1 is a sectional view showing a semiconductor device according to this embodiment;

FIG. 2 is a sectional view showing a semiconductor package according to this embodiment;

FIG. 3 is a plan view showing the semiconductor package shown in FIG. 2;

FIG. 4 is a plan view showing the semiconductor device shown in FIG. 1;

FIG. 5 is a plan view showing an interconnection structure that forms the semiconductor device shown in FIG. 1;

FIG. 6 is a plan view showing the interconnection structure that forms the semiconductor device shown in FIG. 1;

FIG. 7 is a plan view showing the interconnection structure that forms the semiconductor device shown in FIG. 1;

FIG. 8 is a sectional view showing the interconnection structure that forms the semiconductor device shown in FIG. 1;

FIG. 9 is a plan view showing the interconnection structure that forms the semiconductor device shown in FIG. 1;

FIGS. 10A-10B are sectional views showing a production method of the semiconductor device shown in FIG. 1;

FIGS. 11A-11B are sectional views showing the production method of the semiconductor device shown in FIG. 1;

FIGS. 12A-12B are sectional views showing the production method of the semiconductor device shown in FIG. 1;

FIGS. 13A-13B are sectional views showing the production method of the semiconductor device shown in FIG. 1;

FIGS. 14A-14B are sectional views showing the production method of the semiconductor device shown in FIG. 1; and

FIG. 15 is a plan view showing the interconnection structure that forms the semiconductor device shown in FIG. 1.

### DETAILED DESCRIPTION

Hereinafter, an embodiment of the present invention will be described using drawings. Incidentally, in all the drawings, the same symbol is given to the same component and its explanation is omitted appropriately.

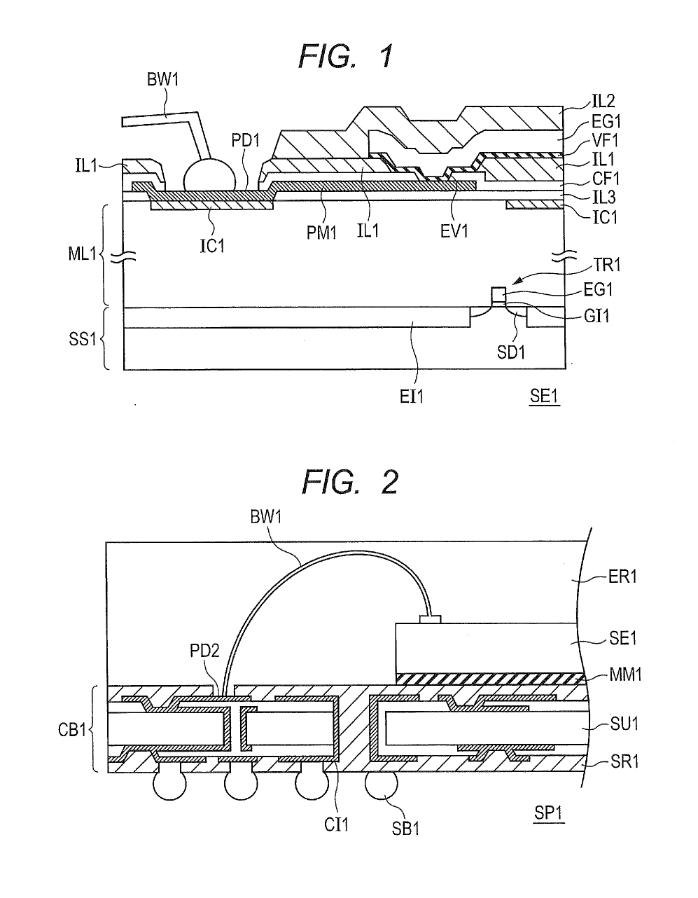

FIG. 1 is a sectional view showing a semiconductor device SE1 according to this embodiment. FIG. 1 is a schematic diagram showing part of the semiconductor device SE1, and a structure of the semiconductor device SE1 is not limited to what is shown in FIG. 1. The semiconductor device SE1 according to this embodiment has a semiconductor substrate SS1, a multilayer interconnection layer ML1, an Al wiring layer PM1, and a redistribution layer EG1. The multilayer interconnection layer ML1 is provided over the semiconductor substrate SS1. The Al wiring layer PM1 is provided over the multilayer interconnection layer ML1 and has pad parts PD1. The redistribution layer EG1 is provided over the Al wiring layer PM1 and couples with the Al wiring layer PM1. Moreover, the redistribution layer EG1 is comprised of a metal material whose electric resistivity is lower than that of Al (aluminum). Furthermore, the redistribution layer EG1 is not formed over the pad parts PD1. Incidentally, in this embodiment, the semiconductor device SE1 is a semiconductor chip. Hereinafter, a configuration of the semiconductor device SE1 according to this embodiment will be explained in detail.

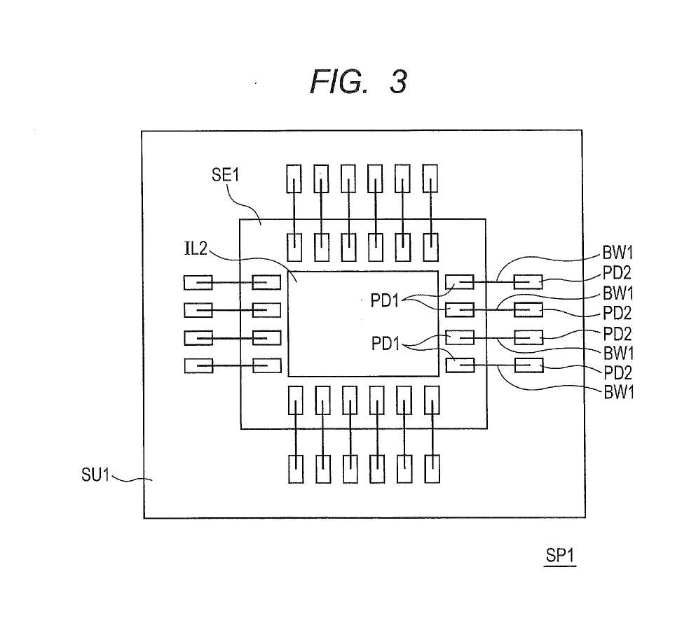

FIG. 2 is a sectional view showing a semiconductor package SP1 according to this embodiment. FIG. 3 is a plan view showing the semiconductor package SP1 shown in FIG. 2. The semiconductor package SP1 according to this embodiment is, for example, a PBGA (Plastic Ball Grid Array), or an FPBGA (Fine-Pitch Plastic Ball Grid Array), or the like. In this embodiment, a package product whose power consumption is equivalent to 5 W is used as the semiconductor package SP1, for example. As shown in FIG. 2, the semiconductor package SP1 according to this embodiment is formed by sealing off the semiconductor device SE1 mounted over a wiring substrate CB1 with sealing resin ER1. The semiconductor device SE1 is fixed over the wiring substrate CBI, for example, with a mounting member MM1 provided over the wiring substrate CB1.

As shown in FIG. 2, the wiring substrate CB1 according to this embodiment has a substrate SU1, wiring layers CI1 provided over both surface of the substrate SU1, solder resist SR1 that covers the substrate SU1 and the wiring layer CI1, and solder balls SB1. The wiring layers CI1 are provided over both surfaces of the substrate SU1. The wiring layers CI1 provided over respective surfaces of the substrate SU1 are mutually coupled through a through hole provided in the substrate SU1. Moreover, the wiring layer CI1 may have a structure, for example, in which multiple layers are stacked on the substrate SU1. The solder resist SR1 has multiple apertures whereby the wiring layer CI1 is exposed. The multiple apertures provided on a surface among surfaces of the wiring substrate CB1 on which the semiconductor device SE1 is mounted form pad parts PD2. Moreover, the solder balls SB1 are formed in multiple apertures provided on a surface opposite to the surface on which the semiconductor device SE1 is mounted in the wiring substrate CB1. The wiring substrate CB1 couples with the outsider through these solder balls SB1.

As shown in FIG. 1, a bonding wire BW1 is coupled to the pad part PD1 provided in the semiconductor device SE1. Moreover, as shown in FIG. 2 and FIG. 3, the semiconductor device SE1 couples with the pad parts PD2 of the wiring substrate CB1 through the bonding wires BW1. By this coupling, the semiconductor device SE1 and the wiring substrate CB1 will be coupled with each other. The bonding wire BW1 is comprised of Au (gold), or Cu (copper), or the like, for example. As shown in FIG. 3, the semiconductor device SE1 has multiple pad parts PD1. The multiple pad parts PD1 are arranged along an outer edge of the semiconductor device SE1. In this embodiment, the multiple pad parts PD1 are arranged along four sides of the semiconductor device SE1 that is a rectangle.

As shown in FIG. 1, the semiconductor device SE1 has the semiconductor substrate SS1. The semiconductor substrate SS1 is a silicon substrate, for example. The multilayer interconnection layer ML1 is formed over the semiconductor substrate SS1. The multilayer interconnection layer ML1 is made by stacking multiple wiring layers one on the other. These multiple wiring layers are mutually coupled through the vias provided among the wiring layers. Each wiring layer and each via are comprised of Cu etc., for example. Incidentally, in FIG. 1, a detailed structure in the inside of the multilayer interconnection layer ML1 is omitted. On the semiconductor substrate SS1, multiple transistors TR1 that are mutually separated, for example, by element isolation regions EI1 are provided. Each of the transistors TR1 includes, for example: a gate insulating film GI1 provided over the semiconductor substrate SS1; a gate electrode GE1 provided over the gate insulating film GI1, and a pair of source and drain areas SD1 that are provided on both sides of the gate electrode GE1 in the semiconductor substrate SS1. The source and drain area SD1 and the gate electrode GE1 of each transistor TR1 are electrically coupled to each other by the wiring that forms the multilayer interconnection layer ML1. Moreover, the wiring that forms the multilayer interconnection layer ML1 electrically couples with the pad parts PD1.

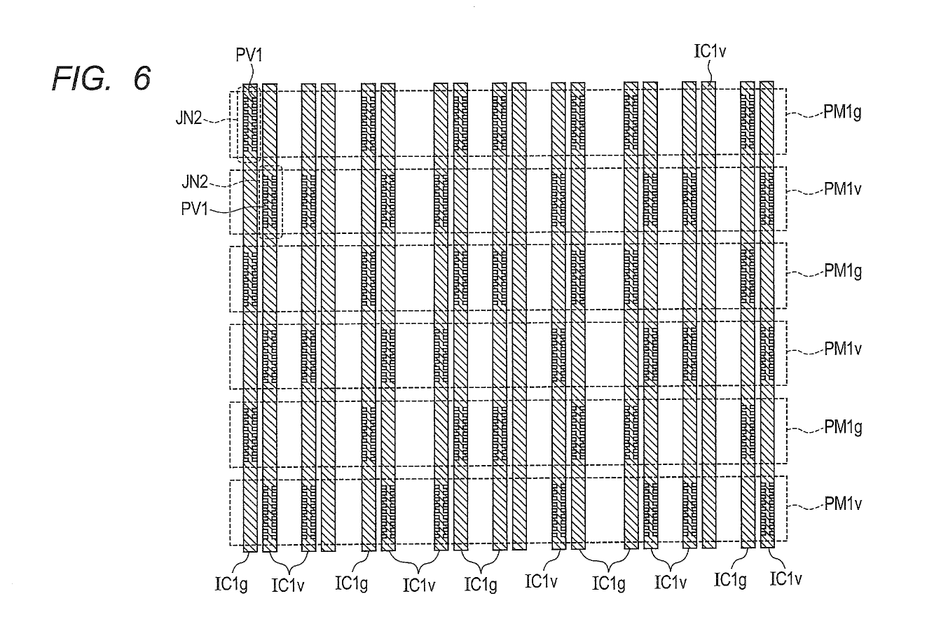

As shown in FIG. 1, over a wiring layer IC1 located as an uppermost layer among the multiple wiring layers that form the multilayer interconnection layer ML1, the Al wiring layer PM1 is provided with intercalation of an insulating film IL3. The Al wiring layer PM1 has the pad parts PD1. Moreover, the Al wiring layer PM1 includes, as a major constitutive film, a film containing Al as a major component, for example. The Al wiring layer PM1 couples with the wiring layer IC1, for example, through a via PV1 (refer to FIG. 6) provided in the aperture formed in the insulating film IL3. Moreover, the Al wiring layer PM1 is provided over the insulating film IL3 provided over the wiring layer IC1. The insulating film IL3 is comprised of an insulating material, such as SiO₂, or SiCN, or the like, for example. Sheet resistance of the Al wiring layer PM1 is, for example, not less than 10 mΩ/sq. and not more than 40 mΩ/sq.

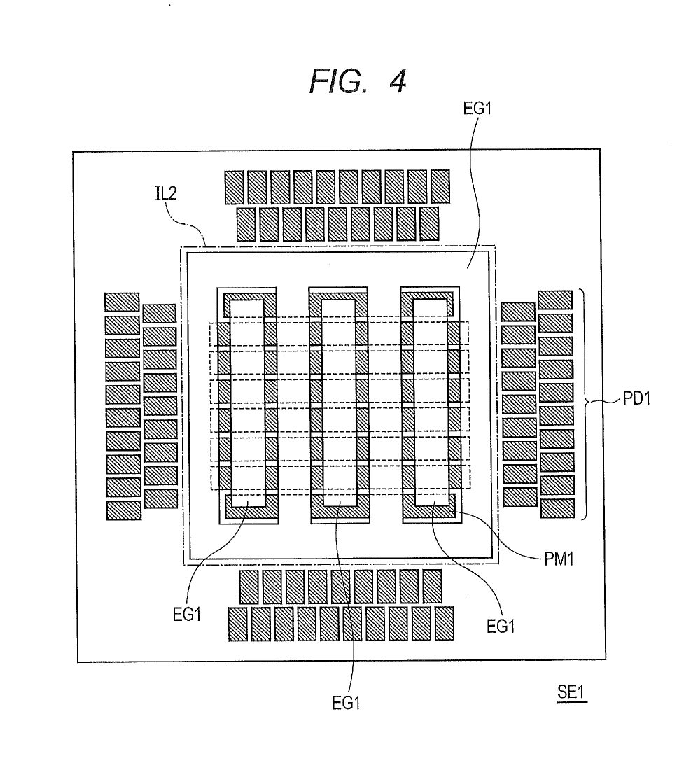

FIG. 4 is a plan view showing the semiconductor device SE1 shown in FIG. 1. Incidentally, FIG. 4 is a schematic diagram for showing an interconnection structure of the redistribution layer EG1 and the Al wiring layer PM1 and showing a spatial relationship between the pad parts PD1 and the Al wiring layer PM1. As shown in FIG. 4, the multiple pad parts PD1 are provided, for example. The multiple pad parts PD1 are located in the outer periphery of an area in which other parts included in the Al wiring layer PM1 are formed, and are arranged so as to enclose that area. By this, the multiple pad parts PD1 will be arranged along the outer edge of the semiconductor device SE1. Moreover, as shown in FIG. 4, the multiple pad parts PD1 may be arranged so as to form multiple rows, such as two rows or three rows, or the like, for example, along the outer edge of the semiconductor device SE1, Moreover, the multiple pad parts PD1 are located in the outside of an area (hereinafter called a redistribution layer EG1 formation area) in which the wiring included in the redistribution layer EG1 is formed in a plan view, and are arranged so as to enclose this area. As will be described later, the Al wiring layer PM1 is provided so as to have a stripe shape part that is comprised, for example, of multiple wirings extending in a second direction (a horizontal direction in FIG. 4). Moreover, the redistribution layer EG1 is provided so as to have a stripe shape part that is comprised, for example, of multiple wirings extending in a first direction (a vertical direction in FIG. 4) that intersects the second direction. The stripe shape part of the Al wiring layer PM1 and the stripe shape part of the redistribution layer EG1 are arranged so as to form a mesh-shaped layout in a plan view. Moreover, the stripe shape part of the Al wiring layer PM1 and the stripe shape part of the redistribution layer EG1 are electrically coupled to each other in their overlapping portions. An insulating layer IL2 provided so as to cover the redistribution layer EG1 formation area is configured so that an end of the insulating layer IL2 may be located in an area between the redistribution layer EG1 formation area and an area in which the pad parts PD1 are formed, in a plan view.

As shown in FIG. 1, the semiconductor device SE1 couples with the wiring substrate CB1 through the bonding wire BW1 coupled to the pad part PD1. Over the pad parts PD1, an other metal layer, such as a metal layer comprised of Au, is not provided. Because of this, the bonding wire BW1 will contact directly the surface of the pad part PD1 comprised of Al, and will be coupled to the pad part PD1. Thereby, connectivity of the bonding wire BW1 and the pad part PD1 can be made excellent. Incidentally, in this embodiment, as shown in FIG. 1, the pad part PD1 is embedded, for example, in the aperture formed in the insulating film IL3. By this, the pad parts PD1 will contact part of the wiring layer IC1 located in its underlying layer.

As shown in FIG. 1, over the Al wiring layer PM1, a cover film CF1 comprised, for example, of an insulating film is provided as a passivation film. The cover film CF1 is comprised, for example, of SiON or SiO₂. Moreover, as shown in FIG. 1, an insulating layer IL1 is formed over the cover film CF1. The insulating layer IL1 is comprised, for example, of polyimide etc. The insulating layer IL1 and the cover film CF1 are formed over the whole surface of the semiconductor device SE1 so as to cover the Al wiring layer PM1 and the insulating film IL3. Because of this, the insulating layer In and the cover film CF1 will be formed also over an area located between the pad parts PD1 and an outer peripheral edge of the semiconductor device SE1, that is, an area located between the pad parts PD1 and scribe lines. The aperture is formed in portions located over the pad parts PD1 of the cover film CF1 and the insulating layer IL1. That is, a wire bonding connection area in which the pad part PD1 and the bonding wire BW1 couple with each other will be formed with a portion exposed from the aperture of the pad part PD1 in the Al wiring layer PM1.

As shown in FIG. 1, over the Al wiring layer PM1, the redistribution layer EG1 coupling with the Al wiring layer PM1 is provided with intercalation with the insulating layer IL1 and the cover film CF1. The redistribution layer EG1 is provided over the insulating layer IL1, and couples with the Al wiring layer PM1 by a via EV1 that penetrates the insulating layer IL1 and the cover film CF1. The redistribution layer EG1 is electrically coupled with the Al wiring layer PM1 through the via EV1 provided in the aperture formed in the insulating layer IL1 and the cover film CF1. The Al wiring layer PM1 formed in one body with the pad parts PD1 is extended to an area in which the wiring that is included in the redistribution layer EG1 is formed in a plan view, and is electrically coupled with the redistribution layer EG1 through the via EV1. Incidentally, for example, the pad part PD1 to which the bonding wire BW1 for transmitting a signal electrically couples is electrically coupled to the multilayer interconnection layer ML1 through the wiring layer IC1, not through the redistribution layer EG1. The redistribution layer EG1 is comprised of a metal material whose electric resistivity is lower than that of Al. In this embodiment, the redistribution layer EG1 is comprised, for example, of Cu (copper) etc. The redistribution layer EG1 includes, as a major constitutive film, a film containing Cu as a major component. A wiring width of a wiring that forms the redistribution layer EG1 is not less than 50 μm and not more than 100 μm, for example. Moreover, a film thickness of the wiring that forms the redistribution layer EG1 is not less than 3 μm and not more than 7 μm, for example. Sheet resistance of the redistribution layer EG1 is, for example, not less than 2 mΩ/sq. and not more than 5 mΩ/sq. Moreover, electric resistivity of the redistribution layer EG1 is ¼ or less of electric resistivity of the Al wiring layer PM1. The electric resistivity of the redistribution layer EG1 can be appropriately selected by a material of the redistribution layer EG1, the wiring width of the wiring that forms the redistribution layer EG1, etc.

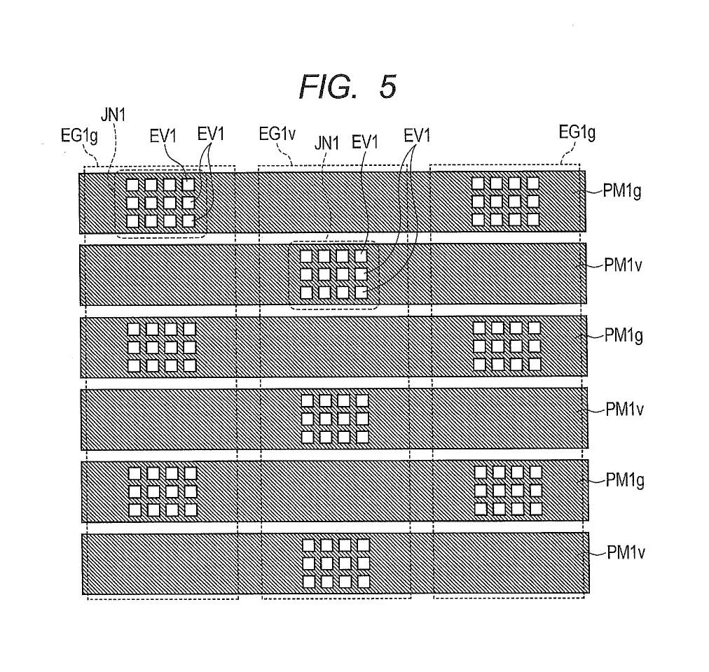

In this embodiment, a power that is supplied to the pad parts PD1 from the outside through the bonding wires BW1 is supplied to the redistribution layer EG1 through the multiple vias EV1 that form coupling parts JN1 (refer to FIG. 5) of the Al wiring layer PM1 and the redistribution layer EG1. The supplied power will be supplied to internal wiring provided in the inside of the semiconductor device SE1 through the redistribution layer EG1. In a plan view, the Al wiring layer PM1 and the redistribution layer EG1 are arranged so as to form a mesh-shaped layout, and are electrically coupled to each other in their overlapping portions. Here, the electric resistivity of the redistribution layer EG1 is lower than the electric resistivity of the Al wiring layer PM1. Because of this, the current loss caused by an IR-Drop can be suppressed more by performing power supply to the internal wiring through the redistribution layer EG1 than by performing the power supply to the internal wiring through the Al wiring layer PM1. Therefore, performing sufficient power supply to the semiconductor device SE1 becomes possible. Moreover, in this embodiment, it becomes possible to control so that a supply voltage supplied to the semiconductor device SE1 may not be lowered as described above, without increasing the number of bonding pads for power supply. Because of this, its operation speed can be improved while attaining miniaturization of the semiconductor device SE1.

As shown in FIG. 1, the redistribution layer EG1 is not formed over the pad parts PD1. Because of this, the pad parts PD1 will be exposed, not being covered with the redistribution layer EG1. In this embodiment, the pad parts PD1 are formed with the Al wiring layer PM1, and are comprised of Al. Since the pad parts PD1 are comprised of Al, the connectivity between the pad parts PD1 and the bonding wire becomes excellent. For this reason, even when forming the redistribution layer EG1, connectivity with the bonding wire can be secured, without forming the redistribution layer EG1 with Au, Therefore, in manufacture of the semiconductor device SE1, it becomes possible to aim at reduction of its cost.

As shown in FIG. 1, barrier metal VF1 is provided under the redistribution layer EG1, for example. The redistribution layer EG1 is formed, for example, by plating the wiring on the barrier metal VF1 provided over the insulating layer IL1. When this is done, the barrier metal VF1 functions, for example, as an electrode. The barrier metal VF1 is comprised of a multilayer film of Cu, Ti (titanium), etc., for example. When the barrier metal VF1 is the multilayer film of Cu and Ti, respective film thicknesses are Cu=300 nm and Ti=100 nm, for example. Moreover, the barrier metal VF1 is formed by performing sputtering, for example, under a condition of RF=250 angstroms.

FIGS. 5 to 7 are plan views showing the interconnection structure that forms the semiconductor device shown in FIG. 1. FIG. 5 schematically shows a structure of the Al wiring layer PM1, the via EV1, and the redistribution layer EG1. The redistribution layer EG1 is shown by a dashed line in FIG. 5. The redistribution layer EG1 shown by the dashed line couples with the Al wiring layer PM1 through the via EV1 provided on the Al wiring layer PM1. As shown in FIG. 5, one wiring of the wirings that form the redistribution layer EG1 couples to multiple wirings that form the Al wiring layer PM1. By this coupling, the power is supplied to the multiple wirings located in the inside of the semiconductor device SE1 in the Al wiring layer PM1 through the redistribution layer EG1 whose electric resistivity is low. Therefore, it becomes possible to suppress a current loss by the IR-Drop and to perform the sufficient power supply to the internal wiring.

As shown in FIG. 5, the Al wiring layer PM1 has the multiple wirings (hereinafter also called first wirings) extending in the first direction (a horizontal direction in FIG. 5). The multiple first wirings are arranged so as to be mutually separated in the second direction (a vertical direction in FIG. 5) that is a direction perpendicular to the first direction of the semiconductor substrate SS1 plane. The Al wiring layer PM1 is configured, for example, so that first wirings PM1v coupling with the power supply and the first wirings PM1g coupling with the ground may be arranged alternately in the second direction. The multiple first wirings PM1v coupling with the power supply are coupled to one another, for example, by an other wiring provided in the outer periphery of an area in which the first wirings PM1v are formed in a plan view. Moreover, the multiple first wirings PM1g coupling with the ground are coupled to one another, for example, by an other wiring provided in the outer periphery of an area in which the first wirings PM1g are formed in a plan view.

As shown in FIG. 5, the redistribution layer EG1 extends in the above-mentioned second direction, and has multiple wirings (hereinafter also called second wirings) each of which intersects the multiple first wirings at right angles in a plan view. The multiple second wirings are arranged so as to be mutually separated in the first direction. The redistribution layer EG1 is configured, for example, so that second wirings EG1v coupling with the power supply and second wirings EG1g coupling with the ground may be arranged alternately in the first direction. The multiple second wirings EG1v coupling with the power supply are mutually coupled, for example, by an other wiring provided in the outer periphery of an area in which the second wirings EG1v are formed in a plan view. Moreover, the multiple second wirings EG1g coupling with the ground are mutually coupled, for example, by an other wiring provided in the outer periphery of an area in which the second wirings EG1g are formed in a plan view.

As shown in FIG. 5, one wiring of the second wirings is coupled with every other first wiring selected from among the multiple first wirings. On the other hand, an other second wiring adjacent to the one wiring of the second wirings is coupled with the first wiring among the multiple first wirings to which the one wiring of the second wirings is not coupled. Moreover, as described above, the second wirings EG1v coupling with the power supply and the second wirings EG1g coupling with the ground are mutually arranged alternately in the first direction. Furthermore, first wirings PM1v coupling with the power supply and the first wirings PM1g coupling with the ground are mutually arranged alternately in the second direction. For this reason, the second wirings EG1v coupling with the power supply will couple with the multiple first wirings PM1v coupling with the power supply. Moreover, the second wirings EG1g coupling with the ground will couple with the multiple first wirings PM1g coupling with the ground.

As shown in FIG. 5, the first wirings that form the Al wiring layer PM1 and the second wirings that form the redistribution layer EG1 are mutually coupled through the coupling part JN1. That is, the redistribution layer EG1 and the Al wiring layer PM1 will be coupled with each other through multiple coupling parts JN1. In this embodiment, the second wirings EG1v coupling with the power supply couple with the multiple first wirings PM1v coupling with the power supply. Moreover, the second wirings EG1g coupling with the ground couple with the multiple first wirings PM1g coupling with the ground. For this reason, the multiple coupling parts JN1 will be arranged in a staggered manner in a plan view. The coupling part JN1 is comprised of the via EV1. As shown in FIG. 5, the coupling part JN1 can be comprised of the multiple vias EV1. This makes it possible to reduce the electric resistance between the redistribution layer EG1 and the Al wiring layer PM1. The via EV1 can be formed, for example, by the same process as that of the redistribution layer EG1. Because of this, the via EV1 is comprised, for example, of Cu etc. like the redistribution layer EG1.

FIG. 6 schematically shows a structure of the wiring layer IC1, the via PV1, and the Al wiring layer PM1. The Al wiring layer PM1 is shown by a dashed line in FIG. 6. The Al wiring layer PM1 shown by the dashed line couples with the wiring layer IC1 through the via PV1 provided on the wiring layer IC1. As shown in FIG. 6, the wiring layer IC1 has multiple wirings (hereinafter also called third wirings) extending in the first direction (a vertical direction in FIG. 6). The multiple third wirings are arranged so as to be mutually separated in the second direction (a horizontal direction in FIG. 6).

As shown in FIG. 6, the multiple third wirings are arranged so that, designating mutually adjoining two wirings of the third wirings as one pair, the multiple pairs thereof may be separated in the second direction. At this time, either of the above-mentioned mutually adjoining two wirings of the third wirings couples to the power supply and the other couples to the ground. Moreover, in mutually adjoining two pairs, either wiring of mutually adjoining two pairs of the third wirings located on a side close to the other pair couples to the power supply, and the other wiring couples to the ground.

As shown in FIG. 6, between the wiring layer IC1 and the Al wiring layer PM1, multiple coupling parts JN2 that couple with these are provided. In this embodiment, the coupling part JN2 establishes coupling of third wirings IC1v coupling with the power supply and the first wirings PM1v coupling with the power supply. Moreover, the coupling part JN2 establishes coupling of the third wirings IC1g coupling with the ground and the first wirings PM1g coupling with the ground. The coupling part JN2 is comprised of the via PV1. As shown in FIG. 6, the coupling part JN2 can be comprised of the multiple vias PV1. This makes it possible to reduce electric resistance between the Al wiring layer PM1 and the wiring layer IC1. The via PV1 can be formed, for example, by the same process as that of the Al wiring layer PM1. Because of this, the via PV1 is comprised, for example, of Al like the Al wiring layer PM1.

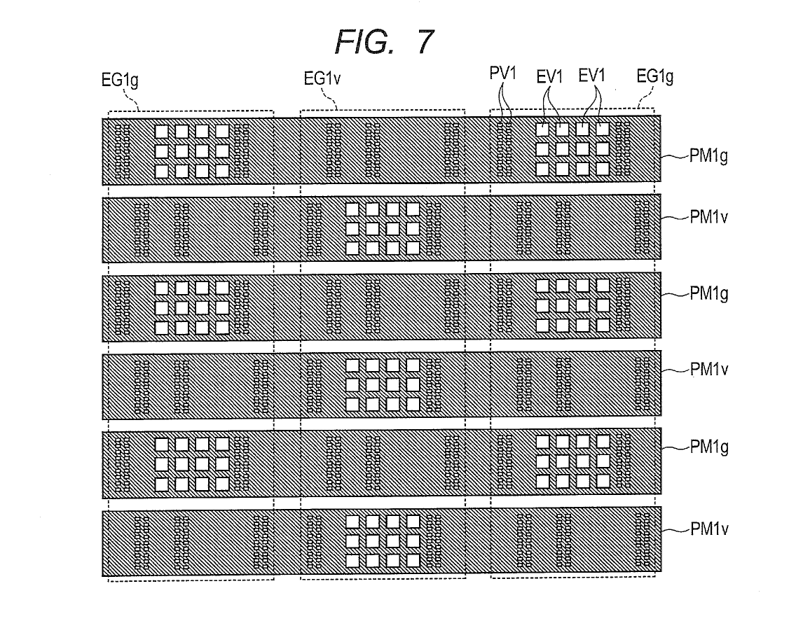

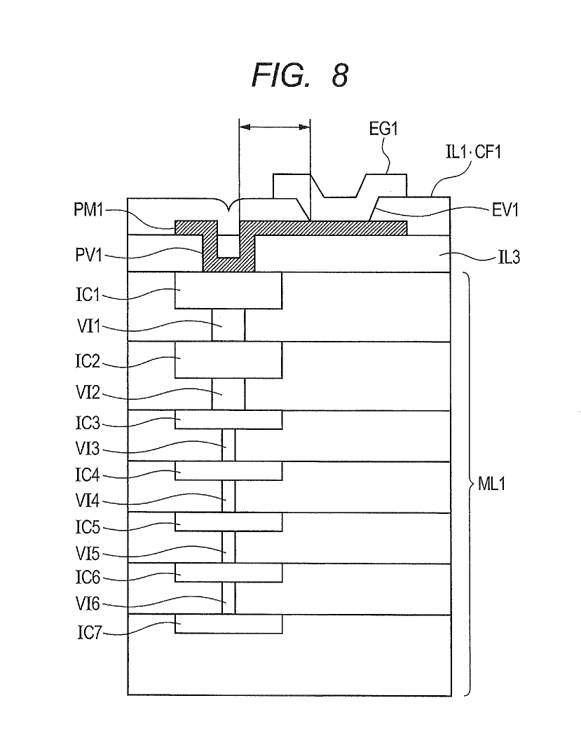

FIG. 7 schematically shows a structure of the Al wiring layer PM1, the via PV1, and the via EV1. FIG. 8 is a sectional view showing the interconnection structure that forms the semiconductor device SE1 shown in FIG. 1. As shown in FIG. 7 and FIG. 8, the via EV1 is arranged, for example, at a position where it does not overlap the via PV1 in a plan view. The via EV1 is provided so as to be separated from the via PV1, for example, by a fixed distance or more in a plan view. When forming the via EV1 over the via PV1, there is a case where a conducting film serving as an electrode at the time of forming the via EV1 by plating may not be sufficiently formed over the via PV1 resulting from poor coverage of the via PV1 comprised of Al. In this case, formation of the via EV1 becomes difficult and there is a possibility that a yield in the manufacture of the semiconductor device SE1 may fall. According to this embodiment, the via EV1 is arranged at a position where it does not overlap the via PV1 in a plan view. This makes formation of the via EV1 easy, and enables the yield in the manufacture of the semiconductor device SE1 to be improved. Incidentally, the conducting film serving as the electrode when the via EV1 is formed by plating is, for example, a Cu/Ti film formed by sputtering.

As shown in FIG. 8, the multilayer interconnection layer ML1 in this embodiment has a multilayer structure in which, for example, a wiring layer IC7, a wiring layer 1C6, a wiring layer IC5, a wiring layer IC4, a wiring layer IC3, a wiring layer IC2, and the wiring layer IC1 are stacked in order. In this case, the following pairs of layers are mutually coupled by respective vias: the wiring layer IC7 and the wiring layer IC6 by a via VI6; the wiring layer IC5 and the wiring layer IC6 by a via VI5; the Wiring layer IC4 and the wiring layer IC5 by a via VI4; the wiring layer IC3 and the wiring layer IC4 by a via VI3; the wiring layer IC2 and the wiring layer IC3 by the via VI2; and the wiring layer IC1 and the wiring layer IC2 by a via VI1. The via PV1, the via VI1, the via VI2, the via VI3, the via VI4, the via VI5, and the via VI6 may overlap mutually in a plan view. Incidentally, as shown in FIG. 8, the wiring layer IC1 located as an upper layer and the wiring layer IC2 are formed, for example, so that their wiring widths may become larger than those of the wiring layers located as their underlying layers. Moreover, for example, the via VI1 and the via VI2 that are located in the upper layer are formed, for example, so that their diameters may become larger than those of the vias located in their underlying layers. For example, each of the wiring layers IC1 to IC7 and each of the vias VI1 to VI6 are formed, for example, by a single damascene process or by a dual damascene process, or by combining these both processes in the interlayer insulating film.

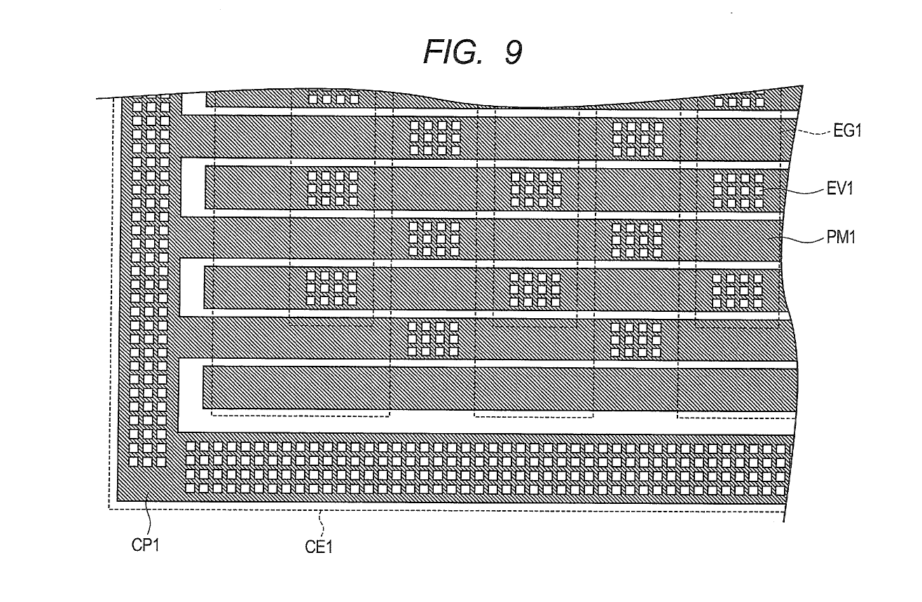

FIG. 9 is a plan view showing the interconnection structure that forms the semiconductor device shown in FIG. 1. FIG. 9 schematically shows a structure of the Al wiring layer PM1, the via EV1, and the redistribution layer EG1. Moreover, FIG. 9 is a plan view showing a structure of an outer periphery part in the interconnection structure that forms the semiconductor device SE1. As shown in FIG. 9, the redistribution layer EG1 is provided, for example, in the shape of a frame, and has an outer peripheral wiring CE1 enclosing other portions that form the redistribution layer EG1. In this embodiment, the outer peripheral wiring CE1 is continuously provided so as to become in the shape of a rectangular frame, for example. The outer peripheral wiring CE1 couples with the second wirings that form the redistribution layer EG1. In this embodiment, the outer peripheral wiring CE1 couples with either the multiple second wirings coupling with the power supply or the multiple second wirings coupling with the ground

As shown in FIG. 9, the Al wiring layer PM1 has an outer peripheral wiring CP1 that encloses other portions forming the Al wiring layer PM1. The outer peripheral wiring CP1 is provided, for example, in the shape of a frame like the outer peripheral wiring CE1. In this embodiment, the outer peripheral wiring CP1 is continuously provided so as to become, for example, in the shape of a rectangular frame. The outer peripheral wiring CP1 couples with the first wirings that form the Al wiring layer PM1. In this embodiment, the outer peripheral wiring CP1 couples with either the multiple first wirings coupling with the power supply or the multiple first wirings coupling with the ground. In this embodiment, the outer peripheral wiring CP1 couples with the first wirings coupling with the power supply in the case where the second wirings with which the outer peripheral wiring CE1 couples couple with the power supply. Moreover, the outer peripheral wiring CP1 couples with the first wirings coupling with the ground in the case where the second wirings with which the outer peripheral wiring CE1 couples couple with the ground.

As shown in FIG. 9, multiple vias PV1 are provided over the outer peripheral wiring CP1. The multiple vias PV1 provided over the outer peripheral wiring CP1 establishes coupling of the outer peripheral wiring CP1 and the outer peripheral wiring CE1. In this embodiment, it is desirable that as many vias PV1 as possible may be provided over the outer peripheral wiring CP1 on a design. Thereby, electric resistance between the outer peripheral wiring CP1 and the outer peripheral wiring CE1 can be reduced.

FIG. 15 is a plan view showing the interconnection structure that forms the semiconductor device shown in FIG. 1, showing a different example from that of FIG. 9. FIG. 15 schematically shows a structure of the Al wiring layer PM1, the via EV1, and the redistribution layer EG1. Moreover, FIG. 15 is a plan view showing a structure of the outer periphery part among the interconnection structures that form the semiconductor device SE1. As shown in FIG. 15, in this embodiment, the outer peripheral wiring CP1 and the outer peripheral wiring CE1 do not need to be provided.

As shown in FIG. 1, the insulating layer IL2 is provided over the redistribution layer EG1. The insulating layer IL2 is provided so as to cover the redistribution layer EG1. Moreover, the insulating layer IL2 is not provided over the pad parts PD1. Because of this, the pad parts PD1 will not be covered with the insulating layer IL2, and will be exposed. As shown in FIG. 4, the insulating layer IL2 is comprised so that the end of the insulating layer IL2 may be located in the area between the redistribution layer EG1 formation area and the area in which the pad parts PD1 are formed, in a plan view. The insulating layer IL2 is formed, for example, with polyimide, etc.

In this embodiment, the insulating layer IL2 is not provided outside the pad parts PD1. That is, the insulating layer IL2 is provided only in an area inside the pad parts PD1 (hereinafter called an inner area), but is not provided over an area located between the pad parts PD1 and the outer peripheral edge of the semiconductor device SE1 (hereinafter called an outer periphery area). In this case, the height of the outer periphery area in which the insulating layer IL2 is not provided becomes lower than the height of the above-mentioned inner area in which the insulating layer IL2 is provided. Thereby, when bonding the bonding wire BW1 to the pad part PD1, it becomes possible to control so that that the capillary used in the bonding may not collide with the insulating layer. Therefore, manufacturing stability of the semiconductor device SE1 can be improved. Moreover, when performing wire bonding of the bonding wire BW1 to the pad part PD1, the height of the bonding wire BW1 can be made low. Because of this, a film thickness of the sealing resin ER1 located over the redistribution layer EG1 can be made thin, and thereby a thickness of the semiconductor package SP1 can be made thin. Incidentally, the pad parts PD1 are located in the outside of an area in which the wirings that are included in the redistribution layer EG1 are formed. Because of this, the redistribution layer EG1 can be covered with the insulating layer IL2 even when the insulating layer IL2 is not provided in the above-mentioned outer periphery area. Therefore, it becomes possible to improve the manufacturing stability of the semiconductor device SE1 as described above, while holding a function of the insulating layer IL2.

As shown in FIG. 1, the outer peripheral edge of the insulating layer IL2 is located inside the pad parts PD1, for example, so as to be separated from the pad parts PD1 in a plan view. The pad parts PD1 are comprised of the Al wiring layer PM1 that is exposed from the aperture provided in the insulating layer ILL By separating the outer peripheral edge of the insulating layer IL2 from the pad parts PD1, it is possible to keep the insulating layer IL2 from entering in the aperture that forms the pad part PD1, and to prevent the aperture from being covered with the insulating layer IL2 when the insulating layer IL2 is formed. Moreover, the outer peripheral edge of the insulating layer IL2 is located over the insulating layer IL1.

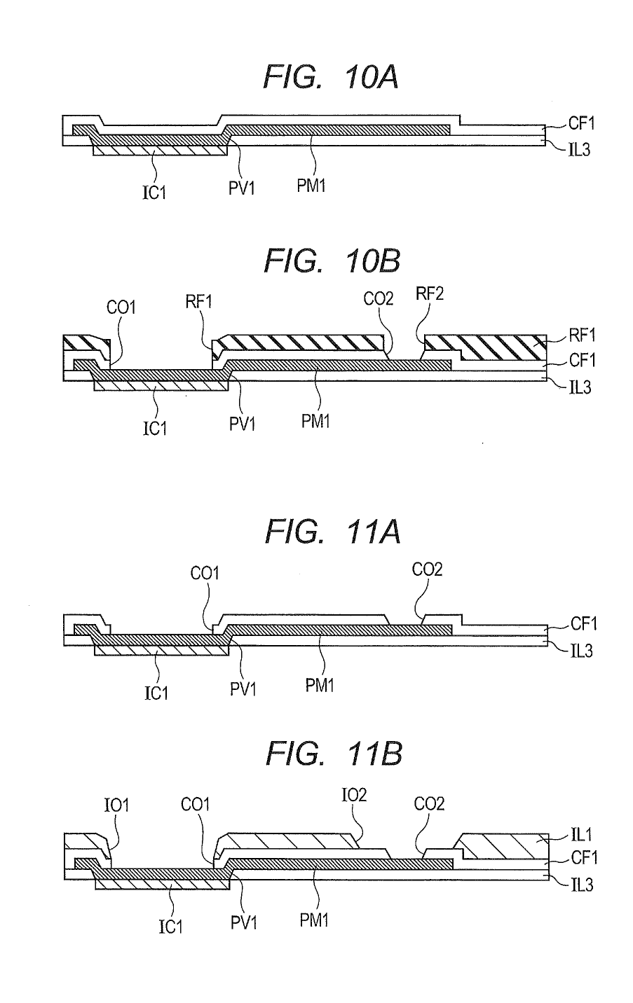

FIGS. 10 to 14 are sectional views showing a production method of the semiconductor device SE1 shown in FIG. 1. The production method of the semiconductor device SE1 according to this embodiment has the steps of: forming the Al wiring layer PM1 having the pad parts PD1 on the multilayer interconnection layer ML1; forming a resist film RF2 having an aperture RO3 that covers the pad parts PD1 and exposes a portion being separated from the pad parts PD1 in the Al wiring layer PM1, on the Al wiring layer PM1; forming the redistribution layer comprised of a metal material whose electric resistivity is lower than that of Al in the aperture RO3 of the resist film RF2; and removing the resist film RF2. Hereinafter, the production method of the semiconductor device SE1 according to this embodiment will be explained in detail.

First, as shown in FIG. 10A, the insulating film IL3 is formed over the wiring layer IC1. Subsequently, an aperture is formed in the insulating film IL3. The aperture includes an aperture for embedding the pad part PD1 and an aperture for embedding the via PV1. Subsequently, an Al layer is formed over the insulating film IL3 and in an aperture formed in the insulating film IL3. Subsequently, the Al wiring layer PM1 is formed by patterning the Al layer by etching etc. Subsequently, the cover film CF1 is formed over the Al wiring layer PM1 and the insulating film IL3 so as to cover the Al wiring layer PM1. Thus, the Al wiring layer PM1 that has the pad parts PD1 is formed over the multilayer interconnection layer ML1.

Next, as shown in FIG. 10B, a resist film RF1 is formed over the cover film CF1. Subsequently, the resist film RF1 is exposed and developed to be patterned into a desired shape. At this time, on the resist film RF1, an aperture RO1 for forming each of multiple apertures CO1 each for exposing the pad part PD1 and an aperture RO1 for forming each of multiple apertures CO2 each for embedding the via EV1 are provided. Subsequently, the cover film CF1 is removed selectively by dry etching using the resist film RF1 as a mask or by other processings. This process forms the multiple apertures CO1 for exposing the pad parts PD1 and the multiple apertures CO2 for embedding the vias EV1. Next, as shown in FIG. 11A, the resist film RF1 is removed.

Next, as shown in FIG. 11B, the insulating layer IL1 is formed over the cover film CF1. The insulating layer IL1 is comprised, for example, of a negative type polyimide. In this case, by developing a portion that should be remained after exposing it, the insulating layer IL1 can be patterned. By patterning the insulating layer IL1, an aperture 101 for exposing the pad part PD1 and an aperture 102 for embedding the via EV1 are formed.

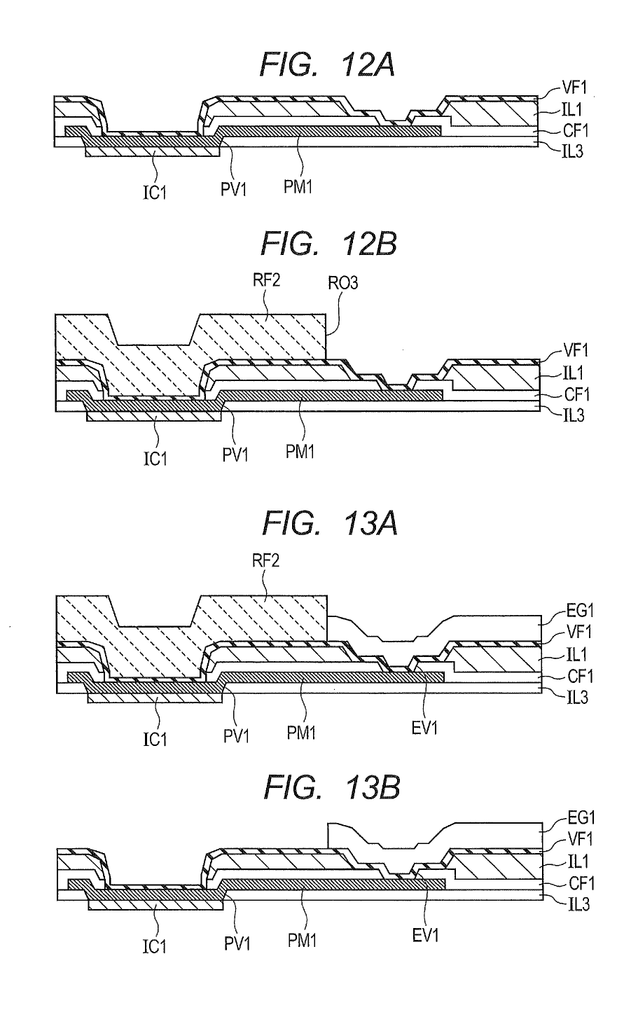

Next, as shown in FIG. 12A, the barrier metal VF1 is formed over the insulating layer IL1 and in the aperture 101 and the aperture 102 formed in the insulating layer IL1. The barrier metal VF1 is formed, for example, by sputtering. Moreover, the barrier metal VF1 is formed by stacking, for example, Cu and Ti sequentially. Next, as shown in FIG. 12B, the resist film RF2 is formed over the barrier metal VF1. Subsequently, the resist film RF2 is patterned by exposing and developing it. This forms an aperture RO3 for forming the Al wiring layer PM1 in the resist film RF2. Thus, the resist film RF2 that covers the pad part PD1 and has the aperture RO3 for exposing a portion being separated from the pad part PD1 in the Al wiring layer PM1 is formed over the Al wiring layer PM1.

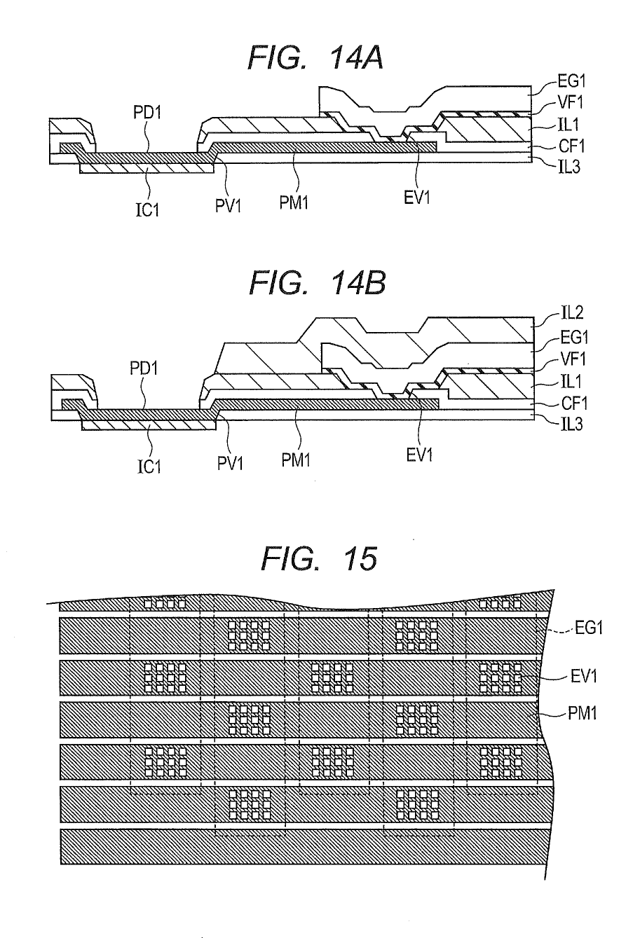

Next, as shown in FIG. 13A, the redistribution layer EG1 is formed in the aperture RO3. The redistribution layer EG1 is formed, for example, by embedding the conducting film comprised of a material whose electric resistivity is lower than that of Al, such as Cu, in the aperture RO3 by a plating method. The plating method is performed, for example, using the barrier metal VF1 as an electrode. This will make the redistribution layer EG1 comprised of a metal material whose electric resistivity is lower than that of Al be formed in the aperture RO3 of the resist film RF2. Next, as shown in FIG. 13B, the resist film RF2 is removed. Next, as shown in FIG. 14A, a portion that is not covered with the redistribution layer EG1 in the barrier metal VF1 is removed selectively. Removal of the barrier metal VF1 is performed, for example, by wet etching with the redistribution layer EG1 used as a mask. In the case where the barrier metal VF1 is comprised of a multilayer film of Cu and Ti, SPM (Sulfuric acid Hydrogen Peroxide Mixture) is used for removal of the Cu layer and APM (Ammonia-hydrogen Peroxide Mixture) is used for removal of the Ti layer. Moreover, after the Ti layer is removed by wet etching using the APM, wet etching using the SPM may be performed in order to remove oxide of Cu.

Next, as shown in FIG. 14B, the insulating layer IL2 is formed over the insulating layer IL1 and the redistribution layer EG1 so as to cover the redistribution layer EG1. The insulating layer IL2 is comprised, for example, of negative type polyimide. In this case, the insulating layer IL2 can be patterned by developing the polyimide after exposure of a portion to be remained. By patterning the insulating layer IL1, it is possible to remain the insulating layer IL2 located inside the pad parts PD1 and to expose the pad parts PD1. Thus, the semiconductor device SE1 shown in FIG. 1 is obtained.

Next, an effect of this embodiment will be explained. According to this embodiment, in the semiconductor device SE1 that has the redistribution layer EG1 comprised of a metal material whose electric resistivity is lower than that of Al over the Al wiring layer PM1 having the pad parts PD1, the redistribution layer EG1 is not provided over the pad parts PD1. Because of this, it is possible to secure connectivity between the pad parts PD1 and the bonding wires BW1 even without using Au as a material that forms the redistribution. Therefore, it is possible to provide the semiconductor device capable of performing the sufficient power supply while suppressing an increase in a manufacturing cost.

Moreover, according to this embodiment, supplying power to the semiconductor device SE1 can be made sufficient in bonding products in each of which the semiconductor device SE1 and the wiring substrate CB1 are coupled with the bonding wire BW1. The bonding products can be manufactured cheaply as compared with flip chip products. According to this embodiment, from such a viewpoint, it is possible to provide the semiconductor device capable of performing the sufficient power supply while suppressing the increase in the manufacturing cost.

Furthermore, according to this embodiment, it becomes possible to strengthen the power that is to be supplied, as described above. That is, if the semiconductor package SP1 is a small package product of small power consumption, the number of bonding pads can be reduced by using the semiconductor device SE1 according to this embodiment. Therefore, it becomes possible to attain the miniaturization of the semiconductor device.

In the foregoing, although the invention made by the present inventors was concretely explained based on the embodiments, it goes without saying that the present invention is not limited to the embodiments, and can be changed variously within a range that does not deviate from its gist.

What is claimed is:

1. A semiconductor device comprising:
a semiconductor substrate;
a multilayer interconnection layer provided over the semiconductor substrate;
an Al wiring layer that is provided over the multilayer interconnection layer and has a pad part; and
a redistribution layer that is provided over the Al wiring layer and couples with the Al wiring layer;
wherein the redistribution layer comprises a metal material whose electric resistivity is lower than that of Al and is not formed over the pad part.

2. The semiconductor device according to claim 1,
wherein the redistribution layer comprises Cu.

3. The semiconductor device according to claim 1,
wherein electric resistivity of the redistribution layer is less than or equal to ¼ of the electric resistivity of the Al wiring layer.

4. The semiconductor device according to claim 1,
wherein a wiring width of wirings that form the redistribution layer is not less than 50 μm and not more than 100 μm.

5. The semiconductor device according to claim 1,
wherein a metal layer comprising Au is not formed over the pad part.

6. The semiconductor device according to claim 1,
wherein the pad part is located outside an area in which wirings that are included in the redistribution layer are formed in a plan view.

7. The semiconductor device according to claim 1,
wherein one wiring of wirings that form the redistribution layer couples to a plurality of wirings that form the Al wiring layer.

8. The semiconductor device according to claim 1,
wherein the Al wiring layer includes a plurality of first wirings extending in a first direction, and
wherein the redistribution layer includes a plurality of second wirings that extend in a second direction perpendicular to the first direction and intersect the first wirings at right angles, respectively, in a plan view.

9. The semiconductor device according to claim 8,
wherein one wiring of the second wirings couples with every other first wiring selected from among the first wirings, and
wherein an other wiring of the second wirings adjacent to the one wiring of the second wirings couples with the first wiring selected from among the first wirings to which the one wiring of the second wirings does not couple.

10. The semiconductor device according to claim 8,
wherein in the redistribution layer, the second wirings coupling with a power supply and the second wirings coupling with the ground are arranged alternately in the first direction.

11. The semiconductor device according to claim 8,
wherein the Al wiring layer and the redistribution layer couple with each other through a plurality of coupling parts, and
wherein the coupling parts are arranged in a staggered manner.

12. The semiconductor device according to claim 1, comprising:
a first via for establishing coupling of the Al wiring layer and a wiring layer located under the Al wiring layer; and
a second via that is provided at a position where it does not overlap the first via in a plan view and establishes coupling of the redistribution layer and the Al wiring layer.

13. The semiconductor device according to claim 1, comprising:
a first insulating layer that is provided over the Al wiring layer and under the redistribution layer; and
a second insulating layer provided over the redistribution layer;
wherein the second insulating layer is not provided outside the pad part.

14. The semiconductor device according to claim 13,
wherein an outer peripheral edge of the second insulating layer is separated from the pad part in a plan view.

15. The semiconductor device according to claim 1,
wherein the redistribution layer is provided in the shape of a frame and has an outer peripheral wiring enclosing other portions that form the redistribution layer.

16. A semiconductor package, comprising:
a wiring substrate;
a semiconductor chip mounted over the wiring substrate; and
a bonding wire that couples with the semiconductor chip and the wiring substrate,
wherein the semiconductor chip has a semiconductor substrate, a multilayer interconnection layer provided over the semiconductor substrate, and a pad part coupling with the bonding wire, and also has an Al wiring layer provided over the multilayer interconnection layer and a redistribution layer that is provided over the Al wiring layer and couples with the Al wiring layer, and
wherein the redistribution layer contains a metal material whose electric resistivity is lower than that of Al and is not formed in the shape of the pad.

17. The semiconductor according to claim 16,
wherein the bonding wire comprises Au or Cu.

18. A production method of a semiconductor device, comprising:
forming an Al wiring layer having a pad part over a multilayer interconnection layer;
forming a resist film that covers the pad part and has an aperture for exposing a portion separated from the pad part in the Al wiring layer over the Al wiring layer;
forming a redistribution layer comprising a metal material whose electric resistivity is lower than that of Al in the aperture of the resist film; and
removing the resist film.
